(19) United States
(12) Patent Application Publication
(10) Pub. No.: US 2025/0131177 A1
(43) Pub. Date: Apr. 24, 2025

(54) QUANTUM COMPUTER DESIGN

(71) Applicant: RHEINISCH-WESTFALISCHE TECHNISCHE HOCHSCHULE (RWTH) AACHEN, Aachen (DE)

(72) Inventors: MATTHIAS KÜNNE, Aachen (DE); PASCAL CERFONTAINE, Aachen (DE)

(21) Appl. No.: 18/722,207

(22) PCT Filed: Dec. 21, 2021
(86) PCT No.: PCT/EP2021/087073

§ 371 Date: Jun. 20, 2024

(51) Int. Cl. G06F 30/398; G06N 10/40; G06N 10/60

(52) U.S. Cl. CPC G06F 30/398; G06N 10/40; G06N 10/60

(57) ABSTRACT

Method for designing a quantum computing element (1) for performing a quantum algorithm, wherein the quantum computing element (1) is configured to be operated with a plurality of spin qubits (9) and has a plurality of shuttling lanes (4) with a plurality of building blocks (13), and wherein the method comprises:
a) providing a respective mathematical model for each of the building blocks (13),
b) providing an initial design of the quantum computing element (1),
c) creating a mathematical model of the initial design by combining the mathematical models of the building blocks (13) according to the initial design,
d) obtaining an improved design of the quantum computing element (1) using the mathematical model of the initial design created in step c) and taking account of the quantum algorithm to be performed with the quantum computing element (1).

### CROSS-REFERENCE TO RELATED APPLICATIONS

This patent application is a continuation of international patent application PCT/EP2021/087073, filed on Dec. 21, 2021, the contents of which are incorporated by referenced herein in their entirety.

### FIELD OF THE INVENTION

The invention is directed to a method for designing a quantum computing element, a respective quantum computing element and an arrangement comprising such a quantum computing element.

### BRIEF DESCRIPTION OF THE RELATED ART

It is known that in theory, quantum computers can outperform conventional computers significantly in specific applications. However, quantum computers existing today have limited capabilities. In particular, there is a desire to develop a universal quantum computer. With prior art quantum computing concepts, however, a useful universal quantum computer would require at least 10⁴ logical qubits with error correction. Today, this appears to be difficult or even impossible to achieve.

From WO 2021/052541 A1 a quantum computing device is known that has a network of shuttling lanes. The elements used therein are further described in WO 2021/052531 A1 (shuttling lanes), WO 2021/052539 A1 (junctions), WO 2021/052538 A1 (loading terminals), WO 2021/052537 A1 (manipulation zones) and WO 2021/052536 A1 (readout terminals). Although the quantum computing device described in these documents is already promising, there is still room for improvement, in particular with respect to achieving universal quantum computing.

In view of the limiting capabilities of prior art quantum computing concepts, it is desirous to use application-specific quantum computing hardware. That is, with universal quantum computing facing challenges, it is desirous to design quantum computing hardware specifically for a certain desired quantum algorithm. However, there is no prior art concept for systematically obtaining such quantum computing hardware.

### SUMMARY OF THE INVENTION

The object of the invention is to provide a concept for systematically designing quantum computing hardware that is specifically configured for performing a given quantum algorithm.

The object is solved with the method, the quantum computing element and the arrangement according to the independent claims. Advantageous refinements are presented in the dependent claims. The features described in the claims and in the description can be combined with each other in any technologically reasonable manner.

According to the invention a method for designing a quantum computing element for performing a quantum algorithm is presented, wherein the quantum computing element is configured to be operated with a plurality of spin qubits and has a plurality of shuttling lanes with a plurality of building blocks, and wherein the method comprises:
a) providing a respective mathematical model for each of the building blocks,
b) providing an initial design of the quantum computing element,
c) creating a mathematical model of the initial design by combining the mathematical models of the building blocks according to the initial design,
d) obtaining an improved design of the quantum computing element using the mathematical model of the initial design created in step c) and taking account of the quantum algorithm to be performed with the quantum computing element.

The method is directed to designing a quantum computing element. The quantum computing element is a piece of hardware. The quantum computing element can be a quantum computer or part of a quantum computer. The quantum computing element can be connected to further quantum computing hardware and/or to further conventional hardware.

The designed quantum computing element, that is the result of the method, is configured for performing a quantum algorithm. Therein, the method is directed to designing the quantum computing element so as to be specifically configured for this quantum algorithm. That is, the purpose of the method is to find a quantum computing element suitably designed for the quantum algorithm. Details of the quantum algorithm and/or of a problem to be solved can therefore be used as an input of the method. Also, a class of problems can be defined and used as an input of the method. Further, details of a conventional algorithm that is supposed to be used in connection with the quantum algorithm can be used as input of the method. Further, the availability of building blocks and/or the qubit type that is supposed to be used can be used as input of the method.

The quantum computing element uses spin qubits. A spin qubit is a two-level quantum system. Preferably, the spin qubits are realized as electron spin qubits or hole spin qubits. An electron spin qubit can be realized with an electron. However, it is also conceivable to realize an electron spin qubit with a group of electrons, for example two or three electrons. In fact, the method can be performed using any conceivable type of spin qubit. An electron can be used as a qubit if the electron spin has been brought into a known state. To this end, an electron can become the realization of a spin qubit by initialization. Usually, a certain qubit remains realized with the same electron throughout an entire quantum algorithm. However, it is also possible that a certain qubit is initialized using a first electron and, after an operation, is realized by means of a second electron. There are even operations after which it is impossible to tell if the qubit is still realized by the first electron or by a different second electron. For performing quantum algorithms this is not a problem since it is sufficient to have the qubit realized in some way at any time. What has been said in this paragraph with respect to electrons applies mutatis mutandis to holes. That is, the quantum computing element can be operated using any conceivable type of hole spin qubit.

The quantum computing element is preferably based on semiconductor technology. That is, the quantum computing element is preferably made with a semiconductor material, particularly preferably with silicon (Si). Preferably, the semiconductor material is silicon germanium (SiGe), in particular undoped silicon germanium. Besides the semiconductor material, the quantum computing element can comprise further materials, in particular metallic contacts. The quantum computing element can be described as a semiconductor heterostructure. Preferably, the quantum computing element comprises a semiconductor substrate, preferably a SiGe substrate or Si substrate. The substrate is preferably undoped. Using semiconductor materials has the advantage that these materials are comparatively easy to handle and inexpensive. This applies in particular to silicon. On top of that, there are well-established techniques for using silicon in computing hardware. Within the substrate a two-dimensional electron gas (2DEG) or a two-dimensional hole gas (2DHG) can be confined. Using gate electrodes, the electrical potential can be manipulated such as to obtain quantum wells or even quantum dots within the 2DEG or 2DHG. Therein, electrons or holes, respectively, can be trapped so that their spin can be used as a realization of a spin qubit. Moving the electrical potentials can move the quantum wells and quantum dots, which can cause a movement of the charge carrier and, hence, of the qubit.

The quantum computing element has shuttling lanes. The spin qubits can be shuttled, that is moved, along the shuttling lanes. This is supposed to be understood such that, for example, the electron or hole realizing the respective spin qubit is shuttled along the shuttling lane. A shuttling lane is a path configured to actively move the spin qubit. In particular, a shuttling lane can be realized using multiple gate electrodes. By varying the electrical potentials of the gates, the electron or hole can be moved. If the electrical potentials of the gates along the shuttling lane are changed in a successive manner, the electron or hole can thus be moved along the shuttling lane. Preferably, the shuttling lanes are arranged on a surface of the substrate of the quantum computing element. The shuttling lanes are preferably straight. That is, the electrons or holes moving along the shuttling lanes do not have to follow a winding or curved path, which would be more difficult to achieve.

The shuttling lanes comprise a plurality of building blocks. A building block can be any installation capable of affecting a spin qubit within the respective shuttling lane. Therein, “affecting a spin qubit” can mean moving the spin qubit, changing a direction of movement of the spin qubit and/or changing a spin state of the spin qubit.

Preferably, the shuttling lanes are arranged so as to form a network of shuttling lanes having multiple junctions. A junction is an example of a building block. It can affect a spin qubit within a shuttling lane to the end that at the junction the direction of movement of the spin qubit can be changed. The junctions are preferably T-junctions. That is, an end of a first shuttling lane is connected to a second shuttling lane at a point spaced apart from the ends of the second shuttling lane. Also, X-junctions are conceivable. Therein, two shuttling lanes meet at a point that is spaced apart from the ends of both shuttling lanes. For practical reasons it can be easier to realize an X-junction by a pair T-junctions. An X-junction is considered to be realized by a pair of T-junctions unless two shuttling lanes cross each other so that both form straight lines at least in the proximity of the X-junction. If, however, one of the two crossing shuttling lanes is offset at the junction, the junction is considered to be realized by a pair of T-junctions.

Further, the quantum computing element preferably comprises manipulation zones. A manipulation zone is an example of a building block. Within a manipulation zone, the state of the spin qubit can be changed. Thereby, quantum operations can be performed. In a manipulation zone a single qubit can be manipulated. The respective operation can be referred to as a single-qubit operation. Also, multiple qubits can be manipulated together in the same manipulation zone. In particular, this can be done with two qubits. The respective operation can be referred to as a multi-qubit operation, in particular as a two-qubit operation.

Preferably, the quantum computing element is configured to be operated by an operation method that respectively comprises for a plurality of spin qubits:
A) initializing the qubit,
B) manipulating the qubit in at least one of the manipulation zones,
C) reading out the qubit.

For each of the qubits steps A) to C) are respectively performed. For each of the qubits, the respective steps A) to C) are preferably performed in the stated order. During steps A) to C) the spin qubit is supposed to remain stable. That is, the qubit state is not supposed to be changed unintentionally or in an arbitrary manner. However, in particular due to decoherence it is possible for spin qubits to lose their state. This unavoidable effect leads to errors that can be dealt with by error correction. Also, decoherence losses can be minimized in that the spin qubits are shuttled distances as short as possible. The coherence time of spin qubits realized in semiconductors depends on the temperature. It is therefore preferred to perform the method with the quantum computing element being placed in a refrigerator at a temperature of less than 4 K, preferably of less than 1 K. In experiments, particularly good results were achieved at 30 mK.

The method for designing the quantum computing element comprises the steps a) to d). These steps are preferably performed in the stated order. However, in particular steps a) and b) can also be performed in any different order.

In step a) a respective mathematical model is provided for each of the building blocks. A mathematical model is a description of the respective building block using mathematical expression and formulas. The mathematical model reflects at least some of the properties of the respective building block that are relevant for performing the quantum algorithm with the quantum computing element. That is, the mathematical model does not have to reflect each detail of the respective building block. It is sufficient that the mathematical model is a simplified representation of the respective building block. For example, the mathematical model can comprise information regarding electrical potentials and magnetic fields, but omit all other physical effects. Preferably, the mathematical model is a dynamical model. That is, the mathematical model covers a certain period of time. This can be realized in that certain points of time within the period of time are taken into account. Preferably, these points of time are equally spaced apart from each other. For example, the mathematical model can comprise information regarding the time evolution of electrical potentials and magnetic fields. Using the mathematical model it can be calculated how a charge carrier such as an electron will move through the quantum computing element and/or how the spin of the charge carrier will evolve. Further, the mathematical model can provide information such as fidelity.

The mathematical model of a certain building block can be considered a digital twin of the building block. That is, before actually manufacturing the quantum computing element or any of its components, it can be predicted, for example, how a charge carrier such as an electron will move through the respective building block and/or how the spin of the charge carrier will be affected within the building block. Alternatively or additionally, the fidelity can be predicted for a certain operation performed with the building block. Having such a digital twin can facilitate the design of the quantum computing element. In particular, using a digital twin can reduce the designing effort significantly, since trial and error is possible without manufacturing any quantum computing element or building block thereof prior to determining the final design.

Preferably, the mathematical model of a respective building block has as inputs a respective value for each electrical signal that would be input into the building block if the building block was actually used. The input preferably depends on the time. That is, if for example a manipulation zone is operated by applying certain electrical control voltages, the mathematical model for this manipulation zone preferably has as input a respective value for each of the electrical control voltages at each point of time within a certain period of time.

Preferably, the mathematical model of a respective building block has as output a respective information on the location of the charge carrier and/or a respective value for its spin state. The information on the location of the charge carrier can be a one-, two- or three-dimensional information. That is, one, two or three values can be provided. Preferably, two dimensions are used. The output preferably depends on the time. The location can be described using a coordinate system. Preferably, the same coordinate system is used for all building blocks. That is, the entire quantum computing element can be described using the same coordinate system.

Preferably, in step a) also a mathematical model for the shuttling lanes is provided. To this end, it is possible to include the shuttling through the shuttling lanes in predicting the behavior of the quantum computing element.

The mathematical models can be provided in step a) in that these models are generated as part of the method. Alternatively, the mathematical models can be provided in step a) in that previously generated mathematical models are selected to be used.

In step b) an initial design of the quantum computing element is provided. In general, the initial design can be any design. That is, in theory, starting from any initial design the described method could provide a suitable result. Although the initial design is preferably capable of performing the quantum algorithm, this is not even necessary. However, it is advantageous to use an initial design that is already as close to an optimal design as possible. The fewer the initial design is amended by the described method, the shorter will the calculation time for performing the method generally be. Also, the result of the method is not necessarily an optimal design, but merely a design that is improved compared to the initial design. In general, it can be expected that the improved design obtained by the described method will be the closer to the optimal design, the closer the initial design already is to the optimal design.

Hence, it is advisable to use what is assumed to be the best design as the initial design in step b). Generally speaking, it is advisable that the initial design is what would be used for manufacturing the quantum computing device if the described method was not performed. That is, any prior art method for designing a quantum computing element can be used in order to obtain the initial design. Generally, the described method will systematically provide further improvement of the initial design.

In step c) a mathematical model of the initial design is created by combining the mathematical models of the building blocks according to the initial design. That is, a digital twin of the quantum computing element is obtained. The mathematical model of the initial design can have as inputs the inputs of the mathematical models of the building blocks involved in the initial design. Therein, it is possible to summarize several inputs of building blocks to a joint input. For example, if in the actual quantum computing element the same electrical voltage is applied to gate electrodes of several of the building blocks, this can be represented in that the mathematical model of the initial design has only one input value for these gate electrodes. Also, the output of the mathematical model of a first building block can be used as input of the mathematical model of a second building block. That is, in dealing with the second building block the mathematical model of the quantum computing element can internally use values obtained for the first building block. To this end, the mathematical model of the initial design can have a number of inputs that is smaller than the sum of the numbers of inputs of the mathematical models of the building blocks.

Preferably, the mathematical model of the initial design has as output a respective information on the location of a charge carrier and/or a respective value for the spin state of the charge carrier. The information on the location of the charge carrier can be a one-, two- or three-dimensional information. That is, one, two or three values can be provided. Preferably, two dimensions are used. The output preferably depends on the time. The location can be described using a coordinate system. Preferably, the same coordinate system is used for all building blocks. That is, the entire quantum computing element can be described using the same coordinate system. Additionally or alternatively, the mathematical model of the initial design can have as output information such as a fidelity.

In step d) an improved design of the quantum computing element is obtained using the mathematical model of the initial design created in step c) and taking account of the quantum algorithm to be performed with the quantum computing element. Compared with the initial design, the improved design can be improved in various respects. For example, the improved design can differ from the initial design in the number and arrangement of the building blocks and/or of the shuttling lanes. In particular, the improved design can be improved in that shuttling distances of the qubits are reduced such that fidelity is increased. Also, the improved design can differ from the initial design in the configuration of one or more of the building blocks. For example, in the improved design the number, arrangement or size of gate electrodes of a building block such as a manipulation zone can differ from the initial design.

The improved design can be obtained by defining one or more variation parameters. Such variation parameters can be, for example, geometrical parameters such as location of a building block, length of a shuttling lane or spacing of gate electrodes of a building block or a shuttling lane. Also, the number of the building blocks, of junctions or of the shuttling lanes can be used as variation parameters. In general, any aspect of the design of the quantum computing element that can be expressed as a parameter and that potentially has an influence on the performance of the quantum computing element can be used as a variation parameter to obtain the improved design in step d). In particular, any input of the mathematical model can be used as such a variation parameter. In general, the more variation parameters are used, the better will the obtained improved design be. However, the number of variation parameters will usually be limited by the available computation power. That is, if too many variation parameters are used, it will be impossible to handle the mathematical model practically and/or the computation time for step d) will be unacceptably long.

For the variation parameter(s) used in step d), respective boundary conditions can be provided. For example, it can be given as a limit that a gate electrode must not be smaller than realizable by available manufacture methods and not larger than what is considered to be reasonable. Also, it can be given as a limit that a voltage must not be larger than what an available voltage source can provide as output voltage. However, it is generally not necessary that for each of the variation parameters respective boundaries are defined.

Initially, the variation parameters are set to values such that the mathematical model reflects the initial design. That is, the starting values for the variation parameters correspond to the initial design.

The improved design can be obtained by varying the variation parameter(s) within the given limits. Thereby, one or more result value(s) can be calculated that are a measure for the suitability of the quantum computing element for the quantum algorithm. For example, such a result value can be a measure for fidelity, degree of difficulty of manufacture, yield, temperature, error rate or computation time. The result value(s) can be obtained from the variation values using the mathematical model. In particular, a target function can be defined and solved, for example numerically.

The improved design is basically obtained by solving mathematical equations. In theory, this could be done manually. However, for practical reasons it is preferred to perform step d) using a computer. Preferably, the computer solves the equations in a numerical manner. In particular, it is preferred to obtain the improved design in step d) by means of a computer simulation. For example, commercially available software such as COMSOL Multiphysics® can be used. With such a software, the initial design can be generated as a three-dimensional computer model, to which material properties and other parameters can be assigned. Also, electrical potentials and magnetic fields can be defined, such that applying an electrical voltage to a gate or placing a magnet at a certain location can be simulated. In general, it is preferred that the three-dimensional model is as detailed as possible and that as many physical parameters such as material properties are defined. However, the more detailed the computer model is, the more difficult to handle will it be. Hence, in practice it will be advisable to choose the level of detail in view of the available computation power. By defining one or more variation parameter(s) and by specifying respective ranges for the variation parameter(s), the software can be used to obtain numerical values of a target function. From the target function, the values for the variation parameters to be used in the improved design can be obtained. In the simplest case, this is done by finding a minimum or maximum of the target function. \The output of the method can include information regarding, in particular, an expected performance, design of logical blocks of conventional and/or quantum algorithms, physical implementation of such blocks and potential overheads, in particular regarding chip layout, control electronics, processes and control signals.

In addition to improving the design of the quantum computing element, also additional electronics can be improved. The additional electronics can be connected to the quantum computing element for controlling the quantum computing element. The additional electronics can be configured as cryo-electronics.

In general, with the described method problems can be solved using a combination of hardware and software in that the hardware is specifically designed for the software to be used. Hence, a hybrid solution can be achieved that involves both hardware and software. This is possible by means of a co-design that can involve chip layout, electronics, processes, control, groups of building blocks and optionally the ability of calibrating and/or robustness.

In a preferred embodiment of the method at least in the improved design the building blocks are arranged in groups, wherein each of the groups is configured to perform a respective quantum sub-algorithm.

Grouping the building blocks can facilitate finding the improved design. For example, for well-known quantum algorithms a respective group can be defined. Such well-known quantum algorithms can include Grover's algorithm or Shore's algorithm. If the quantum algorithm the described method is applied to comprises a sub-algorithm for which a group of building blocks has been defined, this group can be used in the improved design instead of the building blocks that were used in the initial design for the sub-algorithm. Each group of the building blocks can be realized on a respective part of the surface of the quantum computing element. That is, in the present embodiment the optimized quantum algorithm has at least one designated area in which the corresponding sub-algorithm can be executed. Preferably, each of the groups is configured to perform a different quantum sub-algorithm

In an example, the method can be performed using the following steps:
i) identifying a specific problem to be solved,
ii) choosing a quantum algorithm suitable for the problem to be solved,
iii) dividing the quantum algorithm into sub-algorithms,
iv) designing a respective group of building blocks for each of the sub-algorithms,
v) optionally optimizing the groups of building blocks,
vi) optimizing the entirety of the building blocks at least in that interconnections between the groups of building blocks are determined,
vii) optimizing the interconnections between the groups of building blocks, wherein steps i) to vii) are iterated until a desired target criterion is met.

In general, it was found to be advantageous to group the building blocks, wherein each of the groups is configured for a certain sub-algorithm.

In a further preferred embodiment of the method in the initial design the building blocks are arranged in groups, wherein each of the groups is configured to perform a respective quantum sub-algorithm, and wherein in step d) it is determined how to interconnect the groups with each other so as to obtain the improved design.

In this embodiment the building blocks are already grouped in the initial design. Therein, it is not necessary that the initial design is already capable of performing the quantum algorithm. The improved design can be obtained in that the interconnection between the groups is determined. With these interconnections, the improved design is capable of performing the quantum algorithm.

The way the groups of the building blocks are connected to each other can be reflected using one or more variation parameters. Hence, by varying the variation parameters within given limits, various different ways of connecting the groups of building blocks to each other can be compared with each other. Thereby, the improved design can be found.

The interconnects can be realized in the form of shuttling lanes.

In a further preferred embodiment of the method the initial design provided in step b) is a universal design, in which the shuttling lanes form a network having a plurality of identical network cells.

In this embodiment the method starts with a universal design. That is, the effort for step b) is as low as possible. To this end the improved design can be found in a particularly systematic way.

In the universal initial design the network of shuttling lanes is preferably configured with a pattern that repeats itself. Preferably, the network of the shuttling lanes is configured as a grid. Adjacent rows of the grid are preferably offset from each other such that the grid involves only T-junctions rather than X-junctions, which would be more difficult to realize. However, it is not necessary that the network cells have a rectangular shape. It is also possible to have network cells, for example, having a hexagonal shape.

In the universal initial design the network of the shuttling lanes has multiple network cells. Each of the network cells has the same arrangement of shuttling lanes and building blocks. Preferably, each of the network cells comprises one respective manipulation zone as a building block.

The network cells are identical to each other. That is, each network cell has the same arrangement of shuttling lanes and building blocks. The network cells can thus be considered to be copies of a unitary cell. The copies of the unitary cells can be arranged next to each other in rows and columns. This way, the two-dimensional network of the shuttling lanes can be obtained. At its edges, the network can deviate from the described structure based on the unitary cell. That is, at its edges the network might have incomplete copies of the unitary cell or merely shuttling lanes that are not part of a copy of the unitary cell.

Besides the identical network cells the network can have further elements. For example, it is possible that the network cells do not comprise any loading terminals and/or any readout terminals, whereas the network comprises one or more loading terminal(s) and/or one or more readout terminals as such further elements outside the identical network cells. It is sufficient for the network to have only a single loading terminal and only a single readout terminal. A small number of loading terminals and readout terminals can facilitate manufacture. Also, having the loading terminal(s) and readout terminal(s) spaced apart from the qubits during operation can improve the performance. Providing more loading terminals and readout terminals, however, can increase the loading and readout efficiency and reduce the distances the qubits have to be shuttled. In view of this it was found to be reasonable for the network to have one loading terminal per 5 to 20 of the junctions and/or to have one readout terminal per 5 to 20 of the junctions. This is a reasonable definition since the number of the junctions is a measure for the number of the copies of the unitary cell. The junctions can be, in particular, T-junctions or X-junctions. A T-junction counts as one junction and an X-junction counts as one junction. However, if an X-junction is realized by a pair of T-junctions, such an X-junction counts as two junctions. However, it would also be conceivable that each copy of the unitary cell comprises a respective loading terminal. In any case, it is sufficient if each copy of the unitary cell has at most one loading terminal.

It is particularly preferred to have as few loading terminals and as few readout terminals as possible. This is due to the fact that both the loading terminals and the readout terminals can cause heat intake into the quantum computing element, which could reduce the coherence time of the qubits. Ideally, the quantum computing element has only one loading and readout terminal that is used for both loading and readout of all qubits. However, it is already advantageous if the sum of the number of loading terminals, the number of the readout terminals and the number of loading and readout terminals is smaller than the number of network cells, in particular by a factor of at least 10, more particularly even by a factor of at least 100. Since the number of the junctions is a measure for the number of the network cells, it is preferred that the sum of the number of loading terminals, the number of the readout terminals and the number of loading and readout terminals is smaller than the number of the junctions, in particular by a factor of at least 10, more particularly even by a factor of at least 100.

It is conceivable that the number of loading terminals is equal to the number of readout terminals. For example, a ratio between the number of loading terminals and the number of readout terminals can be in the range of 0.5 to 2. However, it would also be conceivable that each copy of the unitary cell comprises a respective readout terminal. In any case, it is sufficient if each copy of the unitary cell has at most one readout terminal.

In a further preferred embodiment of the method the improved design in step d) is obtained from the initial design by omission of at least one part of the initial design.

In this embodiment the improved design has a smaller number of building blocks. This can facilitate manufacture and reduce costs. Also, having fewer building blocks on a quantum computing element can reduce the risk of errors. This is due to the fact that densely packed building blocks are more likely to be defective and more susceptible for cross-talk.

It is particularly preferred to start with the universal initial design described above and to obtain the improved design by omission of at least one of the building blocks of the initial design.

In a further preferred embodiment of the method in step d) it is assessed for each of the building blocks whether or not the respective building block is necessary.

Reducing the number of building blocks can be achieved in that for each building block it is determined whether or not it is necessary. For example, using the mathematical model of the initial design it can be counted for each of the building blocks how many times the respective building block is used for the quantum algorithm. A candidate for the improved design can be obtained from the initial design in that the building block used the least often is omitted. Instead of using this building block, the improved design can be configured such that a different building block is used an additional time.

In a further preferred embodiment of the method in step d) the arrangement of the building blocks according to the initial design is amended so as to obtain the improved design.

In this embodiment the building blocks of the improved design are arranged such that the qubits have to be shuttled over shorter distances compared with the initial design. This can be achieved in that the shuttling distances are calculated for the initial design and compared to various candidates for the improved design.

The arrangement of the building blocks can be expressed as a variation parameter. For example, the location of a certain building block can be described by two coordinates that can be used as variation parameters. By varying these variation parameters within given limits, the improved design can be found, wherein in the improved design the building block is generally arranged in a different location than in the initial design.

In a further preferred embodiment of the method step d) comprises an optimization.

Varying the variation parameters within given limits provides various result values. Ideally, the value(s) for the variation parameter(s) corresponding to the best result value are selected to determine the improved design. This is what is done in the present embodiment. However, a design is already improved compared to the initial design as soon as value(s) for the variation parameter(s) are selected that correspond to a result value that is better than the initial design. That is, in an alternative step d) does not comprise an optimization, but merely an improvement.

In a further preferred embodiment of the method in step b) further an initial instruction for operating the quantum computing element is provided, wherein in step d) further an improved instruction for operating the quantum computing element is obtained

The instructions for operating the quantum computing element can include an information regarding a shuttling path of at least one of the qubits. That is, with the method it can be determined how the qubits are supposed to be shuttled along the shuttling lanes. An improvement can be achieved, for example, in that the shuttling distance is reduced.

The instructions are preferably expressed in terms of variation parameter(s). For example, applied voltages can be used as variation parameters. Also, the path of the qubits can be expressed in terms of variation parameters, for example in that the location of a qubit is expressed by two coordinates for each point of time within a certain period of time.

In an example, the instructions can be improved in that the shuttling direction of a qubit is reversed several times such that this qubit passes a manipulation zone several times. The configuration of the quantum computing element having shuttling lanes is particularly suitable for such kind of improvement. Therein, static and dynamic parameters can be improved.

In a further preferred embodiment of the method the building blocks include loading terminals, manipulation zones, readout terminals and junctions of the shuttling lanes.

As a further aspect of the invention a quantum computing element designed for a specific quantum algorithm is presented, comprising a plurality of shuttling lanes with a plurality of building blocks arranged in groups, wherein each of the groups is configured to perform a respective quantum sub-algorithm, and wherein the groups of the building blocks are interconnected such that the quantum sub-algorithms add up to the quantum algorithm.

The advantages and features of the method are transferrable to the quantum computing element, and vice versa. The quantum computing element is preferably obtained using the described method.

In a preferred embodiment of the quantum computing element the quantum sub-algorithms are different from each other.

As a further aspect of the invention an arrangement is presented that comprises a quantum computing element configured as described and a conventional computer hardware element connected thereto.

The advantages and features of the method and the quantum computing element are transferrable to the arrangement, and vice versa.

### BRIEF DESCRIPTION OF THE DRAWINGS

In the following the invention will be described with respect to the figures. The figures show preferred embodiments, to which the invention is not limited. The figures and the dimensions shown therein are only schematic. The figures show:

FIG. 1a is an initial design of a quantum computing element,

FIG. 1b is an improved design of a quantum computing element, which has been obtained from the initial design by a method according to the invention,

FIG. 1cis an illustration of an alternative way of obtaining an improved design by a method according to the invention,

FIG. 2 is an arrangement according to the invention

FIG. 3 is a part of a shuttling lane of the quantum computing element of FIGS. 1a and 1b,

FIG. 4 is a cross-section of the shuttling lane of FIG. 3,

FIG. 5 is a T-junction of the quantum computing element of FIGS. 1a and 1b,

FIG. 6 is a cross-section of the T-junction of FIG. 5 with a sequence illustrating the development of the electrical potential within the T-junction,

FIG. 7 is a manipulation zone of the quantum computing element of FIGS. 1a and 1b,

FIG. 8 is a cross-section of the manipulation zone of FIG. 7 with a sequence illustrating the development of the electrical potential within the manipulation zone during a single-qubit operation,

FIG. 9 is a cross-section of the manipulation zone of FIG. 7 with a sequence illustrating the development of the electrical potential within the manipulation zone during a two-qubit operation,

FIG. 10 is a loading terminal of the quantum computing element of FIGS. 1a and 1b,

FIG. 11 is a cross-section of the loading terminal of FIG. 10 with a sequence illustrating the development of the electrical potential within the loading terminal during a loading,

FIG. 12 is a readout terminal of the quantum computing element of FIGS. 1a and 1b,

FIG. 13 is a cross-section of the readout terminal of FIG. 12 with a sequence illustrating the development of the electrical potential within the readout terminal during a readout.

### DETAILED DESCRIPTION OF THE INVENTION

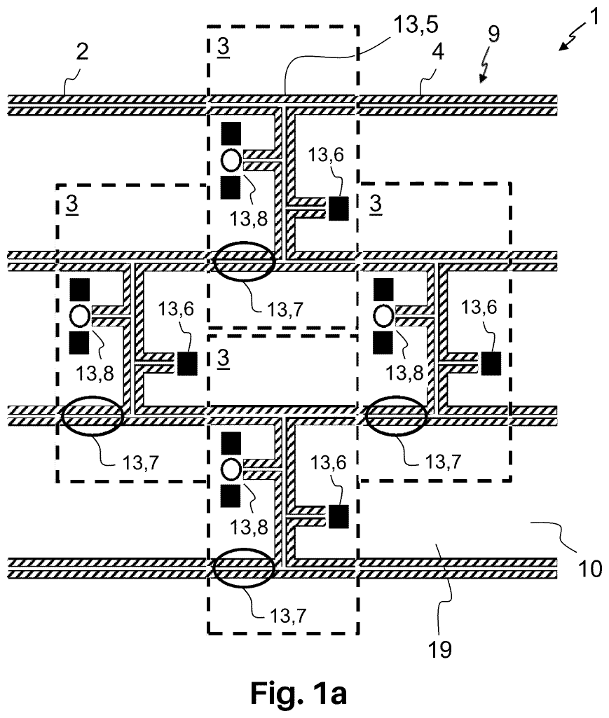

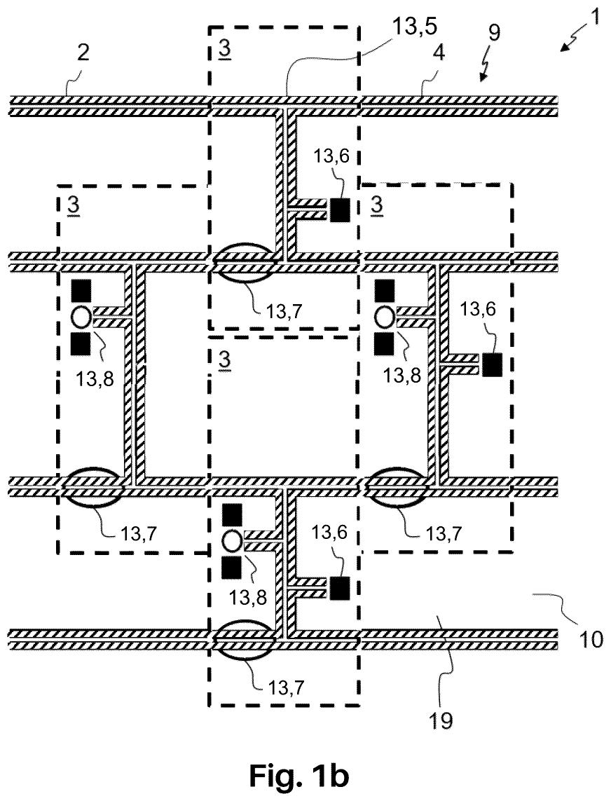

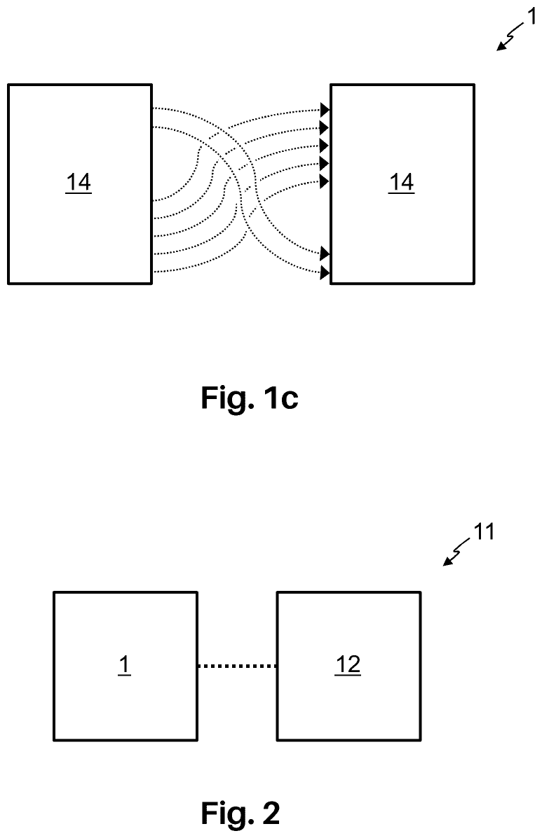

FIG. 1a shows an initial design of a quantum computing element 1. The quantum computing element 1 has a network 2 of shuttling lanes 4 having four network cells 3. The network 2 is realized on a surface 19 of a substrate 10. The network cells 3 have an expansion of the order of 10 μm [micrometers]. The shuttling lanes 4 are connected to each other via junctions 5. Each of the network cells 3 has a respective loading terminal 6, a respective manipulation zone 7 and a respective readout terminal 8. The junctions 5, the loading terminals 6, the manipulation zones 7 and the readout terminals 8 constitute building blocks 13. The quantum computing element 1 is configured for a method which respectively comprises for a plurality of spin qubits 9 (which are merely indicated by a reference numeral assigned to the shuttling lanes 4, since the qubits 9 can be anywhere in the shuttling lanes 4):
A) initializing the qubit 9 by loading a respective electron or hole into the network 2 of the shuttling lanes 4 using one of the loading terminals 6,
B) manipulating the qubit 9 in at least one of the manipulation zones 7,
C) reading out the qubit 9 using one of the readout terminals 8.

Steps A) to C) can be performed simultaneously for at least some of the qubits 9. In particular, the method may comprise multiple adjacent time intervals, wherein in each of the time intervals steps A) to C) are performed for a respective set of the qubits 9.

The qubits 9 can be manipulated in the respective manipulation zone(s) 7 in various ways. For example, at least some of the qubits 9 can be shuttled past the respective manipulation zone 7 in which they are manipulated in step b) and/or at least some of the qubits 9 can have a shuttling direction reversed at the respective manipulation zone 7 in which they are manipulated in step b).

Some or all of the qubits 9 can be successively manipulated in multiple of the manipulation zones 7. These qubits 9 are shuttled in between these manipulation zones 7. For at least some of the qubits 9 the manipulation in the respective step b) can be an entanglement with at least one further of the qubits 9.

The method can be a realization of a surface code.

FIG. 1b shows a design of a quantum computing element 1, which has been improved compared to the design of FIG. 1a. To this end, FIG. 1b shows the result of a method for designing a quantum computing element 1 for performing a quantum algorithm, wherein the quantum computing element 1 is configured to be operated with a plurality of spin qubits 9 and has a plurality of shuttling lanes 4 with a plurality of building blocks 13, and wherein the method comprises:
a) providing a respective mathematical model for each of the building blocks 13,
b) providing the initial design of the quantum computing element 1 according to FIG. 1a,
c) creating a mathematical model of the initial design by combining the mathematical models of the building blocks 13 according to the initial design,
d) obtaining an improved design of the quantum computing element 1 using the mathematical model of the initial design created in step c) and taking account of the quantum algorithm to be performed with the quantum computing element 1.

The improved design shown in FIG. 1b differs from the initial design in that one of the loading terminals 6 and one of the readout terminals 8 has been omitted and in that some of the shuttling lanes 4 have been extended. These differences are merely supposed to exemplarily illustrate how the improved design can differ from the initial design. Depending on the actual quantum algorithm, various other differences between an initial design and an improved design can constitute the improvement form the initial design to the improved design.

FIG. 1c shows an alternative way of how an improved design can be obtained. Therein, the initial design comprises two groups 14 of the building blocks 13 (which are not shown in detail here). Each of the groups 14 is configured to perform a respective quantum sub-algorithm. The improved design is obtained in that it is determined how the groups 14 are supposed to be connected to each other. This is illustrated by dotted arrows.

FIG. 2 shows an arrangement 11 comprising a quantum computing element 1 designed for a specific quantum algorithm, comprising a plurality of shuttling lanes 4 with a plurality of building blocks 13 arranged in groups 14, wherein each of the groups 14 is configured to perform a respective quantum sub-algorithm, and wherein the groups 14 of the building blocks 13 are interconnected such that the quantum sub-algorithms add up to the quantum algorithm. The quantum computing element 1 can be configured as shown in FIG. 1b. Further, the arrangement 11 comprises a conventional computing hardware element 12.

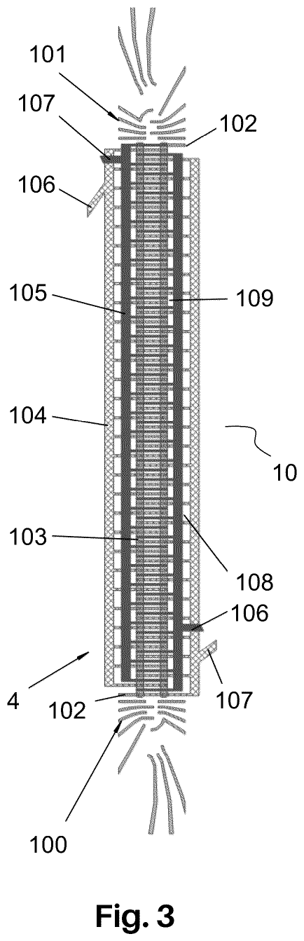

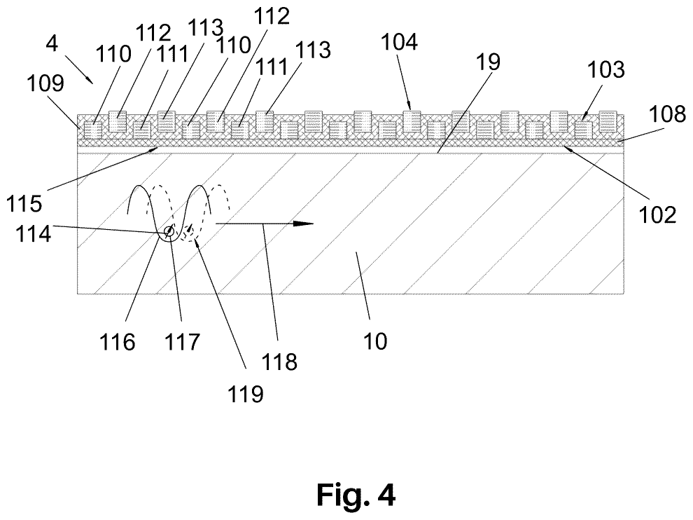

FIGS. 3 and 4 illustrate how the shuttling lanes 4 of the quantum computing element 1 of FIGS. 1a and 1b can be realized. Therefore, FIG. 3 shows schematically a top view of a part of the semiconductor substrate 10 of the quantum computing element 1 of FIGS. 1a and 1b. The part of the semiconductor substrate 10 shown in FIG. 3 includes one of the shuttling lanes 4 that extends between a first side 100 and a second side 101. Therefore, three layers of gate electrode arrays 102, 103, 104 are provided that are separated from each other by insulating layers 108, 109. A respective electrical voltage can be applied to the gate electrode arrays 102, 103, 104 with one or more voltage source(s) (not shown). Therefore, the gate electrode arrays 102, 103, 104 have respective electrical terminals 105, 106, 107.

The first gate electrode array 102 rests on the surface 19 of the substrate 10. The first gate electrode array 102 is followed by the insulating layer 108, on which the second gate electrode array 103 is provided. On top of the second gate electrode array 103 is arranged the insulating layer 109, which electrically isolates the second gate electrode array 103 from the third and uppermost gate electrode array 104.

FIG. 4 shows a cross-section of the part of the substrate 10 shown in FIG. 3. Therein, gate electrodes 115 of the first gate electrode array 102 can be seen. The gate electrode 115 extends longitudinally on the surface 19 of the substrate 10 and is separated from the second gate electrode array 103 by the first insulating layer 108. Of the second gate electrode array 103 electrode fingers 110, 111 are shown partly. The second gate electrode array 103 is delimited from the third gate electrode array 104 by the second insulating layer 109. Of the third gate electrode array 104 only electrode fingers 112, 113 are shown. In this view it is clear how the electrode fingers 110, 111, 112, 113 alternate.

A potential well 116 is created by applying sinusoidal voltages to the gate electrode arrays 102, 103, 104. A quantum dot 117 trapped in this potential well 116 can be moved through the substrate 10. The potential well 116 is moved longitudinally through the substrate 10 by driving the electrode fingers 110, 111, 112, 113 with sinusoidal voltages without changing the quantum mechanical properties of the quantum dot 117. The movement of quantum dot 117 in the direction of arrow 118 is indicated by dashed lines 119. The quantum mechanical state is indicated by the small arrow 114 of the quantum dot 117.

Voltage is applied to the gate electrode arrays 102, 103, 104 such that the electrode fingers 110, 111, 112, 113 form the movable potential well 116 in the substrate 10. By controlling the gate electrode arrays 102, 103, 104, the potential well 116 can be moved along the shuttling lane 4 through the substrate 10. The second gate electrode array 103 and the third gate electrode array 104 are provided with sinusoidal voltages.

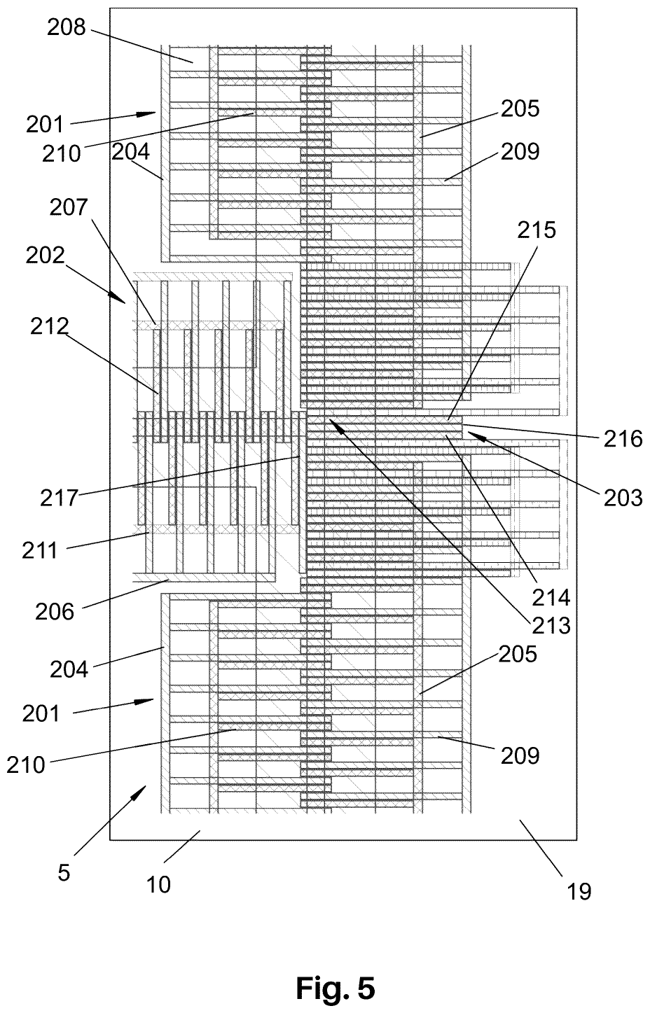

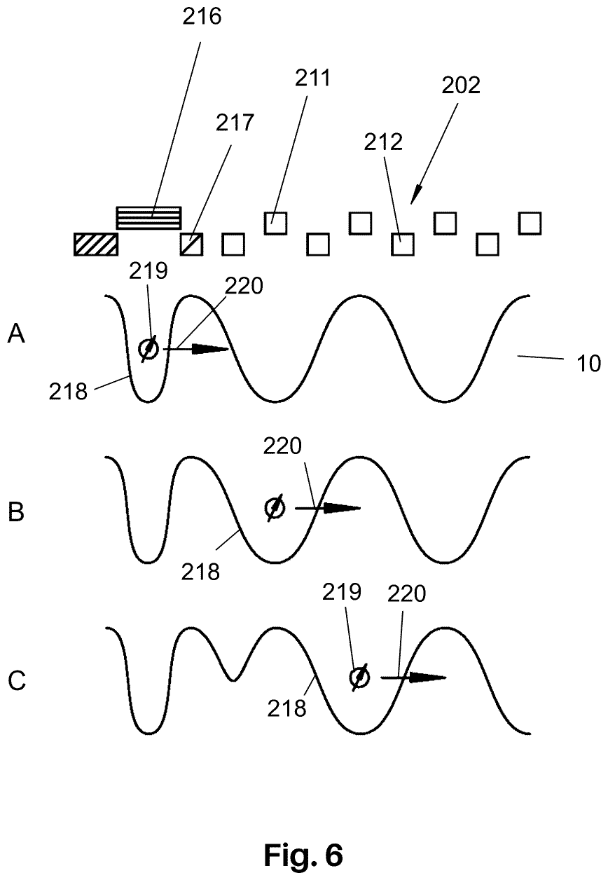

FIGS. 5 and 6 illustrate how the junctions 5 of the quantum computing element 1 of FIGS. 1a and 1b can be realized. Therefore, FIG. 5 shows a part of the semiconductor substrate 10 of the quantum computing element 1 of FIGS. 1a and 1b. The part of the semiconductor substrate 10 shown in FIG. 5 includes one of the T-junctions 5.

The quantum computing device 1 is configured such that a two-dimensional electron gas (2DEG) is contained within the substrate 10. Gate electrode arrays 201, 202, 203 are provided on the surface 19 of the substrate 10. The gate electrode arrays 201, 202, 203 contribute to defining the shuttling lanes 4 in that the gate electrode arrays 201, 202, 203 manipulate the electrical potential within the substrate 10 such that electrons of the 2DEG can be moved in a controlled manner.

The gate electrode arrays 201, 202, 203 each comprise two respective gate electrodes 204, 205, 206, 207. The individual gate electrodes 204, 205, 206, 207 are electrically separated from each other by insulating layers 208. For this purpose, the gate electrode arrays 201, 202, 203 are constructed in layers, with the insulating layers 208 being provided between the gate electrodes 204, 205, 206, 207. The gate electrodes 204, 205, 206, 207 further comprise electrode fingers 209, 210, 211, 212. The electrode fingers 209, 210, 211, 212 of a certain gate electrode 204, 205, 206, 207 are arranged parallel to each other on the surface 19 of the substrate 10.

The gate electrode arrays 201, 202, 203 can be supplied with an electrical voltage via electrical connections (not shown in detail). By applying sinusoidal voltages to the gate electrodes 204, 205, 206, 207 of the gate electrode arrays 201, 202, a potential well can be generated within the substrate 10. A quantum dot trapped in this potential well can thus be moved through the substrate 10. The potential well can be moved longitudinally through the substrate 10 by applying sinusoidal voltages to the electrode fingers 209, 210, 211, 212.

Within the quantum dot a single electron can be trapped. If the quantum dot is moved, the electron will be moved along therewith. The spin of this trapped electron can be used as a spin qubit 9. To this end it is possible to shuttle qubits 9 through the shuttling lanes 4 with the junction 5. Therein, the electron is moved together with the quantum dot in which it is trapped. This process is continuous in that the electron remains within the same quantum dot throughout its journey passing the junction 5. The electron does not have to tunnel into a different quantum dot in order to change direction at the junction 5.

The gate electrode array 202 branches off from the gate electrode array 201 in a crossing region 213. The gate electrode arrangement 203 is disposed in the crossing region 213. The gate electrode array 203 includes two barrier gate electrodes 214, 215. The barrier gate electrodes 214, 215 can be switched on when the moving potential well with the quantum dot is located in the crossing region 213. By switching on the barrier gate electrodes 214, 215, the potential well with the quantum dot is held in the crossing region 213. A pump gate electrode 216 of the gate electrode array 203 can cause the potential well with the quantum dot to change direction towards the gate electrode array 202.

Provided that no change of direction is to be made by the potential well with the quantum dot, a barrier gate electrode 217 of the gate electrode array 203 is activated. The other two barrier gate electrodes 214, 215 are switched off. The barrier gate electrode 217 thus blocks access to the gate electrode array 202. The quantum dot in the moving potential well thus has no reason to change direction. To this end a T-junction 5 is realized through which a qubit 9 can be moved. Depending on the applied voltages, it can be decided through which branch of the junction 5 the qubit 9 leaves the junction 5.

FIG. 6 shows a cross-section through the part of the semiconductor substrate 10 of FIG. 5. For reasons of clarity, only the electrode fingers 211, 212, the barrier gate electrode 217 and the pump gate electrodes 216 are shown. Underneath, a sequence A to C is shown that illustrates a movement of a potential well 218 with a quantum dot 219.

The electrode fingers 211, 212 of the gate electrode array 202 form the moving potential well 218. The movement of the potential well 218 is effected by interconnecting the electrode fingers 211, 212. For this purpose, the electrode fingers 211, 212 of the gate electrode array 201 are periodically interconnected in an alternating manner, which causes a nearly continuous movement of the potential well 218 through the substrate 10. In FIG. 6 it is illustrated how the potential well 218 with the quantum dot 219 is branched off from the intersection region 213. The moving potential well 218 is located in the direction of the gate electrode array 202. The arrow 220 indicates the direction of movement of the potential well 218 with the quantum dot 219.

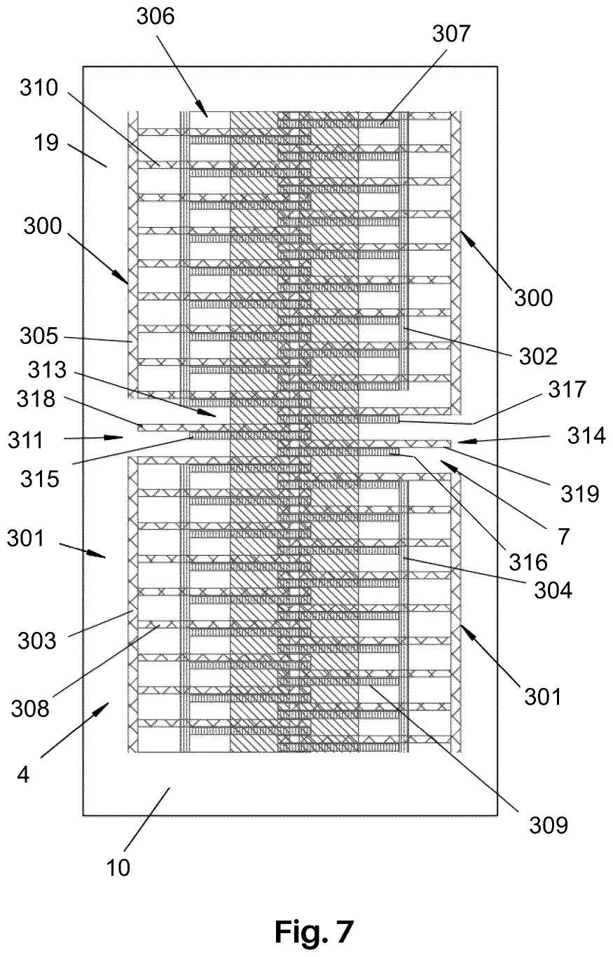

In FIG. 7 a manipulation zone 7 of the quantum computing element 1 of FIGS. 1a and 1b is shown. Gate electrode arrays 300, 301, 314 are provided on a surface 19 of the substrate 10. The gate electrode arrays 300, 301 each include two gate electrodes 302, 303, 304, 305. The individual gate electrodes 302, 303, 304, 305 are electrically separated from each other by insulating layers 306. The gate electrode arrays 300, 301 are provided in layers, wherein an insulating layer 306 is provided between each gate electrode 302, 303, 304, 305 of the gate electrode arrays 300, 301. The gate electrodes 302, 303, 304, 305 further comprise electrode fingers 307, 308, 309, 310 arranged parallel to each other on the surface 19 of the substrate 10.

The manipulation zone 7 is formed in an area 311 where the gate electrode arrays 300, 301 abut each other. A manipulator 313, which includes the gate electrode array 314, is located in the manipulation zone 7. The gate electrode array 314 includes barrier gate electrodes 315, 316, 317 which form at least one static potential well. The gate electrode array 314 further includes pump gate electrodes 318, 319, each of which can cause a quantum dot or a charge carrier to move or oscillate.

An electrical voltage is applied to the gate electrode arrays 300, 301, 314 via electrical connections. By applying sinusoidal voltages to the gate electrodes 302, 303, 304, 305 of the gate electrode arrays 300, 301, a potential well is created in the substrate 10. A quantum dot or charge carrier trapped in this potential well can be moved through the substrate 10. The potential well is moved longitudinally through the substrate 10 by appropriately driving the electrode fingers 307, 308, 309, 310 with sinusoidal voltages.

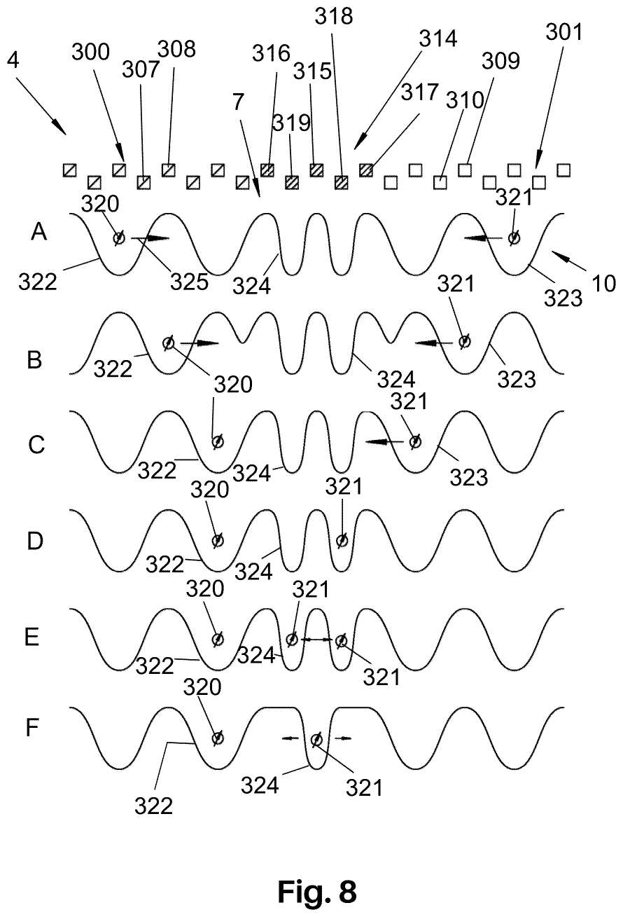

FIG. 8 illustrates the sequence of a manipulation of a charge carrier in a quantum dot 320, 321 in the manipulation zone 7 for a single-qubit operation. Therefore, a sectional view of the manipulation zone 7 is shown, wherein only the electrode fingers 307, 308, 309, 310, the barrier gate electrodes 315, 316, 317 and the pump gate electrodes 318, 319 are shown. Underneath, there is a sequences A to F of the propagation of potential wells 322, 323 in the substrate 10. Although a single-qubit operation is illustrated by FIG. 8, two quantum dots 320, 321 are shown that are trapped in the quantum wells 322, 323. The single-qubit operation is performed within the manipulation zone 7 using the quantum dot 321, while the other quantum dot 320 “waits” outside the manipulation zone 7. This can be useful in that subsequently to the single-qubit operation a two-qubit operation can be performed that involves both quantum dots 320, 321.

The electrode fingers 307, 30, 32 34 of the gate electrode arrays 300, 301 form the potential wells 322 and 323. The movement of the potential wells 322, 323 is effected by interconnecting the electrode fingers 307, 308, 309, 310 appropriately. For this purpose, the electrode fingers 307, 308, 309, 310 of the gate electrode arrays 300, 301 are periodically interconnected in an alternating manner, which cause a nearly continuous movement of the potential wells 322, 323 through the substrate 10.

A static double well 324 is formed in the manipulation zone 7. The static

double well 324 is created by the barrier gate electrodes 315, 316, 317. First, the quantum dot 321 is brought in with the movable potential well 323 to the static double potential well 324 in the manipulation zone 7. This is indicated by a horizontal arrow 325. The manipulator 313, for example a gradient magnetic field, allows the quantum dot 321 to assume a defined quantum mechanical state. The other quantum dot 320 waits outside the manipulation zone 7. By moving in the magnetic field gradient of the manipulator 313, a defined quantum state of the quantum dot 321 is achieved. It is now possible for the quantum dot 321 to assume a defined quantum state by delocalizing in the double well (E) or by moving rapidly back and forth in the magnetic field gradient (F). When guided away from the manipulation zone 7, the quantum dot 321 thus has a defined quantum mechanical state.

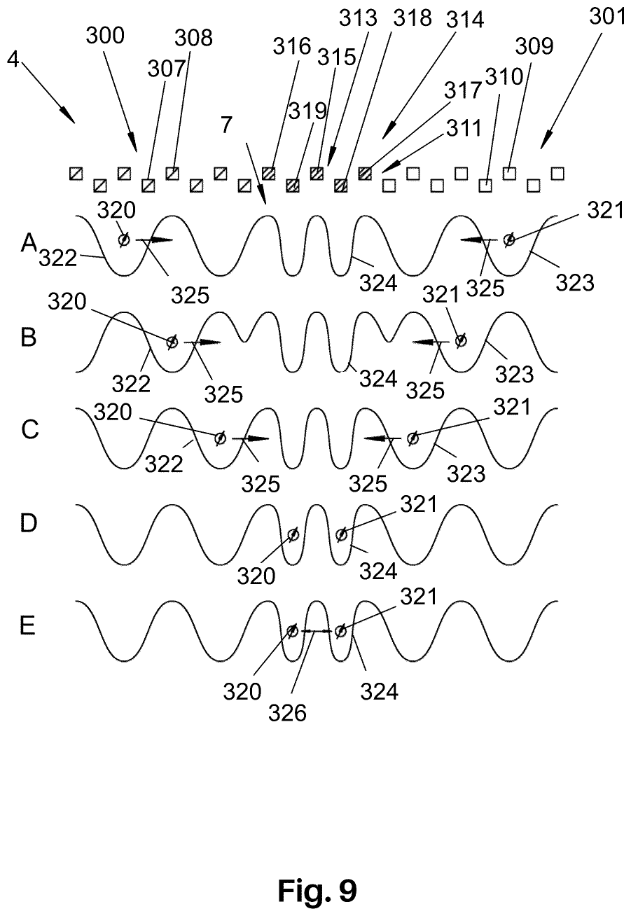

FIG. 9 illustrates the sequence of a manipulation in the manipulation zone 7 of a two-qubit operation. Therein, a static double well 324 is formed in the manipulation zone 7 by the barrier gate electrodes 315, 316, 317. Quantum dots 320, 321 are moved to the static double potential well 324 in the manipulation zone 7 by the movable potential wells 322, 323 and each is introduced into the double potential well 324. The manipulator 313, for example a gradient magnetic field, allows the quantum dots 320, 321 to assume a defined quantum mechanical state. Two-qubit operations can be performed between the quantum dots 320, 321 by exchange interaction, which is indicated by a horizontal double arrow 326. Thus, the quantum dots 320, 321 moved away from the manipulation zone 312 acquire defined quantum mechanical states.

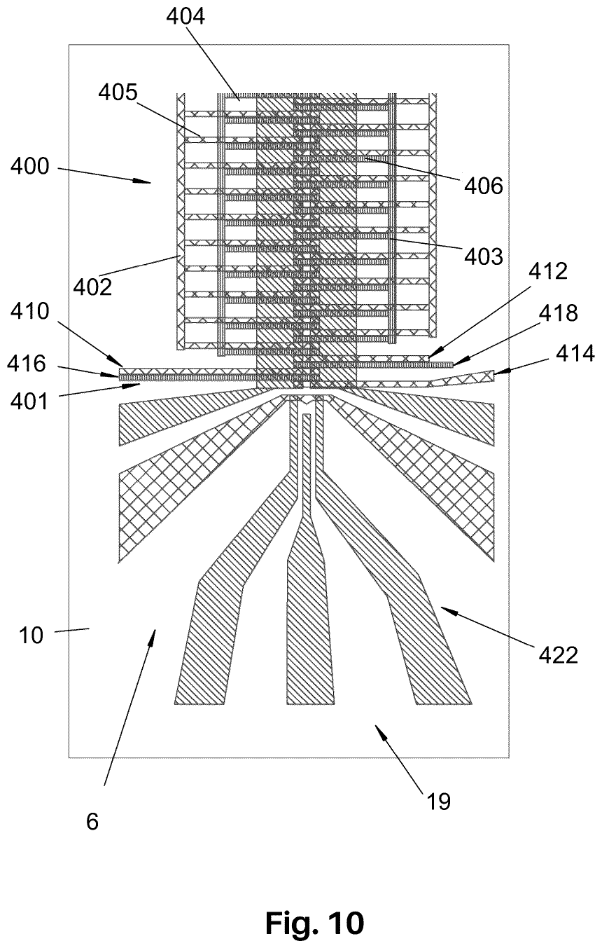

In FIG. 10 a loading terminal 6 of the quantum computing element 1 of FIGS. 1a and 1b is shown. Gate electrode arrays 400, 401 are provided on the surface 19 of the substrate 10. The gate electrode array 400 has two gate electrodes 402, 403. The individual gate electrodes 402, 403 are electrically separated from each other by insulating layers 404. The gate electrodes 402, 403 of the gate electrode array 400 are provided in layers for this purpose, with the insulating layer 404 being provided between each gate electrode 402, 403 of the gate electrode array 400. The gate electrodes 402, 403 further comprise electrode fingers 405, 406 arranged parallel to each other on the surface 19 of the substrate 10.

Voltage is applied to the gate electrode arrays 400, 401 via electrical connections. By applying sinusoidal voltages to the gate electrodes 402, 403 of the gate electrode array 400, a movable potential well is created in the substrate 10. A quantum dot 408 or charge carrier trapped in this potential well can thus be moved through the substrate 10. The potential well is moved longitudinally through the substrate 10 by driving the electrode fingers 405, 406 of the gate electrodes 402, 403 with sinusoidal voltages.

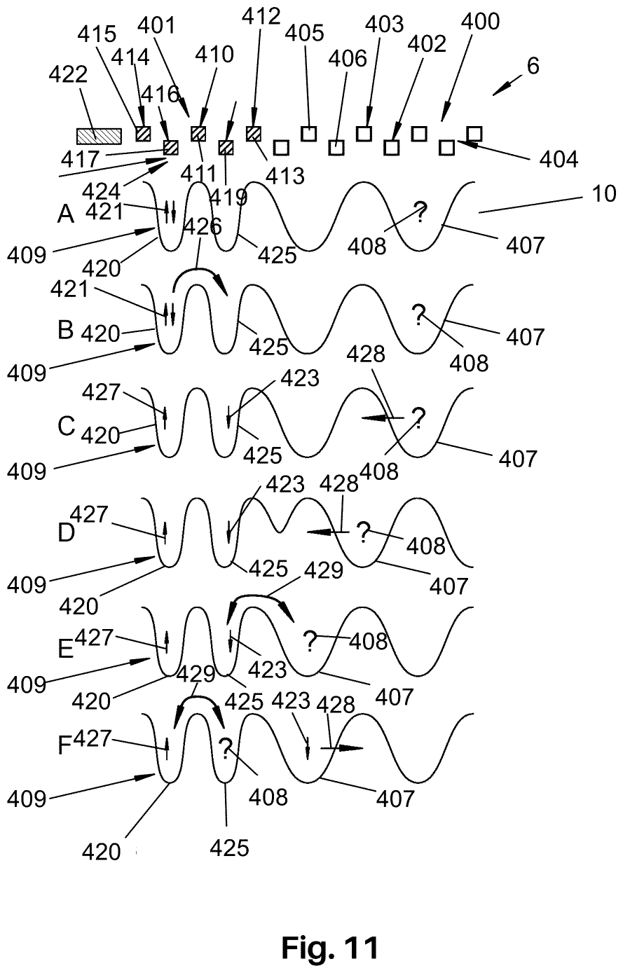

The gate electrode array 401 forms a static double potential well. For this purpose, the gate electrode array 401 comprises barrier gate electrodes 410, 412, 414, a pump gate electrode 416 and a further pump gate electrode 418 which can set a quantum dot or a charge carrier in motion or oscillation. The pump gate electrodes 416, 418 are arranged alternately between the barrier gate electrodes 410, 412 and 414. The gate electrodes 410, 412, 414, 416, 418 each have electrode fingers 411, 413, 415, 417, 419 (which are labelled with reference signs in FIG. 11). Connected to the barrier gate electrode 410, 412, 414 of gate electrode array 401 is a reservoir 422 for introducing charge changes.

FIG. 11 illustrates the sequence A to F of loading a charge carrier. The electrode fingers 405, 406 of the gate electrode array 400 form potential wells 407 that are movable through the substrate 10. The movement of the potential wells 407 is thereby effected by a suitable interconnection of the electrode fingers 405, 406. For this purpose, the electrode fingers 405, 406 of the gate electrode array 400 are periodically interconnected in an alternating manner, which cause a nearly continuous movement of the potential well 407 through the substrate 10.

The loading terminal 6 is based on the Pauli principle, according to which an electronic level can never be occupied by electrons of the same spin. By means of the gate electrodes 410, 412, 414 and 416, 418, a static double potential well 409 is generated on the one hand and the movable potential well 407 is generated on the other hand by means of the gate electrodes 402, 403. Two charge carriers 421 from the reservoir 422 are introduced into a first potential well 420 of the static double potential well 409. The charge carriers 421 are split and aligned with a stimulator 424, for example using a gradient magnetic field and the pump gate electrodes 416, 418. A split-off charge carrier 423 tunnels into a second static potential well 425 of the double potential well 409, which is indicated by arrow 426. Only one charge carrier 427 remains in the first static potential well 420. The quantum states of the quantum dots 423, 427 in the potential wells 420, 421 are known by the orientation of an applied gradient magnetic field.

By means of the movable potential well 407, another quantum dot 408 is brought to the second static potential well 425 of the double potential well 409 in the same level. The quantum mechanical state of the quantum dot 408 is not known. Arrow 428 indicates the translation direction of quantum dot 408 with moving potential well 407. By tunneling effect, the quantum dot 423 of the second static potential well 425 exchanges with the quantum dot 408 of the moving potential well 407. The known quantum mechanical state of the quantum dot 423 is now in the moving potential well 407 and initializes, for example, a qubit.

The quantum dot 408 tunnels, if it has the same spin as the quantum dot 423 now moved away to initialize, back into the first static potential well 420 of the double potential well 409. Thus, a sensor element not shown here would not detect any change in charge. If the quantum mechanical states of the quantum dot 423 and 408 are different, a charge change could be detected. The exchange by tunneling is symbolized by arrow 429.

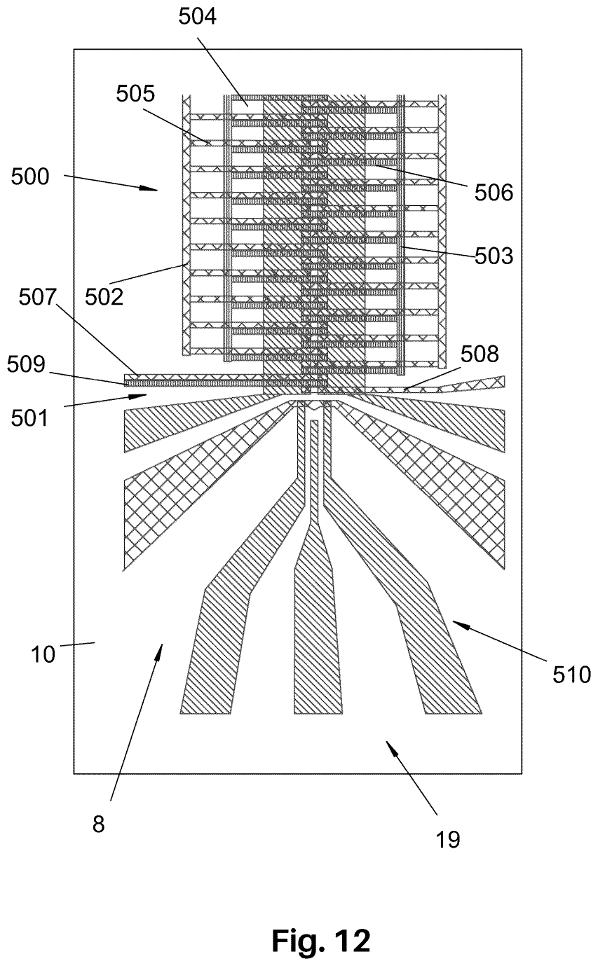

In FIG. 12 a readout terminal 8 of the quantum computing element 1 of FIGS. 1a and 1b is shown. Therein, gate electrode arrays 500, 501 are shown that each includes two gate electrodes 502, 503. The individual gate electrodes 502, 503 are electrically separated from each other by insulating layers 504. The gate electrode arrays 500, 501 are provided in layers for this purpose, with the insulating layer 504 being provided between each gate electrode 502, 503. The gate electrodes 502, 503 further comprise electrode fingers 505, 506 arranged parallel to each other on the surface 19 of the substrate 10.

Suitable voltage is applied to the gate electrode arrays 500, 501 via electrical connections. By applying sinusoidal voltages to the gate electrodes 502, 503 of the gate electrode array 500, a potential well is created in the substrate 10. A quantum dot or charge carrier trapped in this potential well can thus be moved through the substrate 10. The potential well is moved longitudinally through the substrate 10 by driving the electrode fingers 505, 506 with sinusoidal voltages.

The gate electrode array 500 forms a region in which a quantum dot can be moved by means of a potential well. In contrast, the gate electrode array 501 forms a static potential well. For this purpose, the gate electrode array 501 comprises barrier gate electrodes 507, 508 and a pump gate electrode 509 which can set a quantum dot or a charge carrier in motion or oscillation. The pump gate electrode 509 is arranged between the barrier gate electrodes 507, 508. The gate electrodes 507, 508 and 509 are also each separated by an insulating layer 504.

Connected to the barrier gate electrode array 501 is a sensor element 510 for detecting changes in charge. The sensor element 510 detects the charge present in the static potential well. The potential well is generated by the gate electrode array 501.

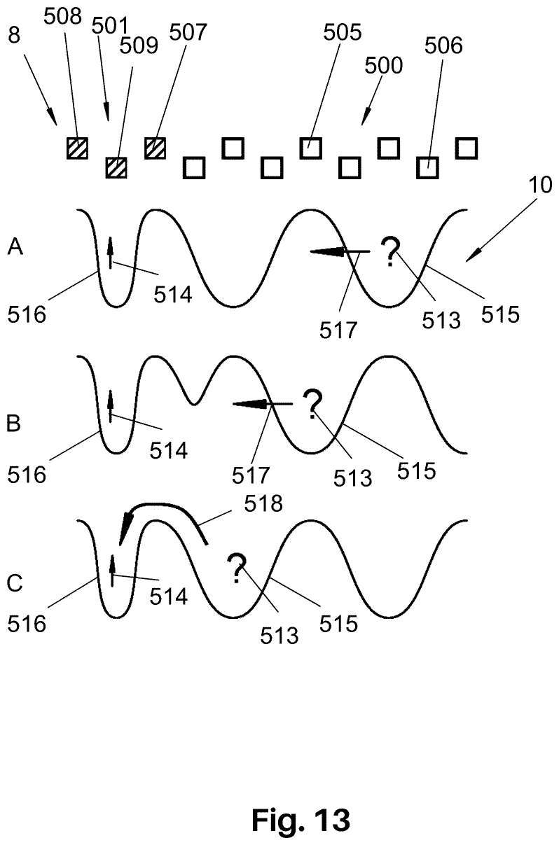

FIG. 13 illustrates the sequence for a readout of a quantum state of a qubit in a quantum dot 513. The figure shows the readout terminal 8 in a simplified manner so that only the electrode fingers 505, 506, the barrier gate electrodes 507, 508 and the pump gate electrodes 509 are visible. Underneath, sequences from A to C of the courses of potential wells 515, 516 are shown. The electrode fingers 505, 506 of the gate electrode array 500 form the moving potential well 515. The movement of the quantum dot 513 in the potential well 515 is thereby effected by the suitable interconnection of the electrode fingers 505, 506. For this purpose, the electrode fingers 505, 506 of the gate electrode array 500 are periodically interconnected in an alternating manner, which cause a nearly continuous movement of the quantum dot 513 in the potential well 515 through the substrate 10.

The readout terminal is based on the Pauli principle. By means of the gate electrodes 507, 508, on the one hand, the static potential well 516 is generated and, on the other hand, the movable potential well 515 is generated by means of the gate electrodes 505, 506. A quantum dot 513, of which the quantum mechanical state at a level—in the case of an electron, the spin—is known, is introduced into the static potential well 516. The quantum dot 513 is aligned with the pump gate electrode 508, e.g., spin-up, as shown here. By means of the movable potential well 515, another quantum dot 514 is brought up to the static potential well 516 at the same level. Arrow 517 indicates the direction of the movement of the quantum dot 514 with movable potential well 515. If the quantum mechanical states are different, the level is now filled. The filling up can be done by tunneling, which is symbolized by arrow 518.

The sensor element 510 detects a changed charge on this level in the case that a quantum dot has been added. If the quantum mechanical states of the quantum dots 513, 514 are the same, then the level cannot accept another charge carrier. Thus, the quantum mechanical state does not change at this level. Thus, it can be determined which quantum mechanical state the approached quantum dot 513 has.

### LIST OF REFERENCE NUMERALS

1 quantum computing element
2 network
3 network cell
4 shuttling lane
5 junction
6 loading terminal
7 manipulation zone
8 readout terminal
9 spin qubit
10 substrate
11 arrangement
12 conventional computer hardware element
13 building block
14 group
19 surface
100 first side
101 second side
102 first gate electrode array
103 second gate electrode array
104 third gate electrode array
105 electrical terminal
106 electrical terminal
107 electrical terminal
108 first isolation layer
109 second isolation layer
110 electrode finger (second layer)
111 electrode finger (second layer)
112 electrode finger (third layer)
113 electrode finger (third layer)
114 arrow
115 gate electrodes (first layer)
116 potential well
117 quantum dot
118 direction of arrow
119 dashed line
201 gate electrode array
202 gate electrode array
203 gate electrode array
204 gate electrodes
205 gate electrodes
206 gate electrodes
207 gate electrodes
208 insulating layers
209 electrode fingers
210 electrode fingers
211 electrode fingers
212 electrode finger
213 crossing region
214 barrier gate electrode
215 barrier gate electrode
216 pump gate electrode
217 barrier gate electrode
218 moving potential well
219 quantum dot
220 arrow
300 gate electrode array
301 gate electrode array
302 gate electrode
303 gate electrode
304 gate electrode
305 gate electrode
306 insulating layer
307 electrode finger
308 electrode finger
309 electrode finger
310 electrode finger
311 area
313 manipulator
314 gate electrode array
315 barrier gate electrodes
316 barrier gate electrodes
317 barrier gate electrodes
318 pump gate electrodes
319 pump gate electrodes
320 quantum dot
321 quantum dot
322 moving potential well
323 moving potential well
324 static double well
325 horizontal arrow
326 horizontal double arrow
400 gate electrode array
401 gate electrode array
402 gate electrode
403 gate electrode
404 insulating layers
405 electrode finger
406 electrode finger
407 potential well
408 quantum dot
409 static double potential well
410 barrier gate electrode
411 electrode finger
412 barrier gate electrode
413 electrode finger
414 barrier gate electrode
415 electrode finger
416 pump gate electrode
417 electrode finger
418 pump gate electrode
419 electrode finger
420 1st static potential well
421 charge carrier
422 reservoir
423 split-off quantum dot
424 stimulator
425 2nd static potential well
426 arrow (tunneling)
427 remaining quantum dot
428 arrow (translation)
429 arrow (exchange interaction)
500 gate electrode array
501 gate electrode array
502 gate electrodes
503 gate electrodes
504 insulating layer
505 electrode finger
506 electrode finger
507 barrier gate electrode
508 barrier gate electrode
508 pump gate electrode
510 sensor element
513 quantum dot
514 quantum dot
515 moving potential well
516 static potential well
517 arrow (translation)
518 arrow (tunneling)

1. A method for designing a quantum computing element for performing a quantum algorithm, wherein the quantum computing element is configured to be operated with a plurality of spin qubits and has a plurality of shuttling lanes with a plurality of building blocks, and wherein the method comprises:
a) providing a respective mathematical model for each of the building blocks,
b) providing an initial design of the quantum computing element,
c) creating a mathematical model of the initial design by combining the mathematical models of the building blocks (according to the initial design,
d) obtaining an improved design of the quantum computing element using the mathematical model of the initial design created in step c) and taking account of the quantum algorithm to be performed with the quantum computing element.

2. The method according to claim 1, wherein at least in the improved design the building blocks are arranged in groups, and wherein each of the groups is configured to perform a respective quantum sub-algorithm.

3. The method according to claim 1, wherein in the initial design the building blocks (are arranged in groups, wherein each of the groups is configured to perform a respective quantum sub-algorithm, and wherein in step d) it is determined how to interconnect the groups with each other so as to obtain the improved design.

4. The method according to claim 1, wherein the initial design provided in step b) is a universal design, in which the shuttling lanes form a network having a plurality of identical network cells.

5. The method according to claim 4, wherein the improved design in step d) is obtained from the initial design by omission of at least one part of the initial design.

6. The method according to claim 1, wherein in step d) it is assessed for each of the building blocks whether or not the respective building block is necessary.

7. The method according to claim 1, wherein in step d) the arrangement of the building blocks according to the initial design is amended so as to obtain the improved design.

8. The method according to claim 1, wherein step d) comprises an optimization.

9. The method according to claim 1, wherein in step b) further an initial instruction for operating the quantum computing element is provided, and wherein in step d) further an improved instruction for operating the quantum computing element is obtained.

10. The method according to claim 1, wherein the building blocks include loading terminals, manipulation zones, readout terminals and junctions of the shuttling lanes.

11. A quantum computing element designed for a specific quantum algorithm, comprising a plurality of shuttling lanes with a plurality of building blocks arranged in groups, wherein each of the groups is configured to perform a respective quantum sub-algorithm, and wherein the groups of the building blocks are interconnected such that the quantum sub-algorithms add up to the quantum algorithm.

12. The quantum computing element according to claim 11, wherein the quantum sub-algorithms are different from each other.

13. An arrangement comprising a quantum computing element according to claim 11 and a conventional computer hardware element connected thereto.
